(19) United States
(12) Patent Application Publication
(10) Pub. No.: US 2023/0128551 A1
(43) Pub. Date: Apr. 27, 2023

(54) EDGE RING FOR LOCALIZED DELIVERY OF TUNING GAS

(71) Applicant: LAM RESEARCH CORPORATION, Fremont, CA (US)

(72) Inventors: Yohan SEEPERSAD, Fremont, CA (US); Ryan BISE, Campell, CA (US); John HOLLAND, San Jose, CA (US); Leonid BELAU, Pleasanton, CA (US); Adam Christopher MACE, Morgan Hill, CA (US)

(21) Appl. No.: 17/915,573

(22) PCT Filed: Mar. 12, 2021
(86) PCT No.: PCT/US2021/022036

§ 371 Date: Sep. 29, 2022

Related U.S. Application Data
(60) Provisional application No. 63/041,694, filed on Jun. 19, 2020.
(60) Provisional application No. 63/004,132, filed on Apr. 2, 2020.

(51) Int. Cl. C23C 16/458; H01J 37/32; C23C 16/455; H01L 21/687

(52) U.S. Cl. CPC C23C 16/4585; H01J 37/32642; C23C 16/45521; H01L 21/68735; H01J 37/32715; H01J 37/32449; H01J 2237/3321; H01J 2237/335; H01J 2237/3343

(57) ABSTRACT

An edge ring for a substrate processing system includes an annular body and an annular channel disposed in the annular body circumferentially along an inner diameter of the annular body. The annular channel includes N distinct sections, where N is an integer greater than 1. The edge ring includes N injection ports arranged circumferentially on the annular body to respectively inject one or more gases into the N distinct sections of the annular channel. The edge ring includes a flange extending radially inwards from the inner diameter of the annular body. A plurality of slits is arranged in the flange. The slits are in fluid communication with the annular channel and extend radially inwards from the annular channel to deliver the one or more gases.

### CROSS-REFERENCE TO RELATED APPLICATIONS

This application claims the benefit of U.S. Provisional Application No. 63/004,132, filed on Apr. 2, 2020 and U.S. Provisional Application No. 63/041,694, filed on Jun. 19, 2020. The entire disclosures of the applications referenced above are incorporated herein by reference.

### FIELD

The present disclosure relates generally to substrate processing systems and more particularly to an edge ring for localized delivery of tuning gas.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

A substrate processing system typically includes a plurality of processing chambers (also called process modules) to perform deposition, etching, and other treatments of substrates such as semiconductor wafers. Examples of processes that may be performed on a substrate include, but are not limited to, a plasma enhanced chemical vapor deposition (PECVD), a chemically enhanced plasma vapor deposition (CEPVD), a sputtering physical vapor deposition (PVD), atomic layer deposition (ALD), and plasma enhanced ALD (PEALD). Additional examples of processes that may be performed on a substrate include, but are not limited to, etching (e.g., chemical etching, plasma etching, reactive ion etching, etc.) and cleaning processes.

During processing, a substrate is arranged on a substrate support such as a pedestal, an electrostatic chuck (ESC), and so on in a processing chamber of the substrate processing system. A computer-controlled robot typically transfers substrates from one processing chamber to another in a sequence in which the substrates are to be processed. During deposition, gas mixtures including one or more precursors are introduced into the processing chamber, and plasma is struck to activate chemical reactions. During etching, gas mixtures including etch gases are introduced into the processing chamber, and plasma is struck to activate chemical reactions. The processing chambers are periodically cleaned by supplying a cleaning gas into the processing chamber and striking plasma.

### SUMMARY

An edge ring for a substrate processing system comprises an annular body and an annular channel disposed in the annular body circumferentially along an inner diameter of the annular body. The annular channel includes N distinct sections, where N is an integer greater than 1. The edge ring comprises N injection ports arranged circumferentially on the annular body to respectively inject one or more gases into the N distinct sections of the annular channel. The edge ring comprises a flange extending radially inwards from the inner diameter of the annular body. A plurality of slits is arranged in the flange. The slits are in fluid communication with the annular channel and extend radially inwards from the annular channel to deliver the one or more gases.

In another feature, the plurality of slits is configured to deliver the one or more gases to an upper periphery of a substrate support assembly and under an outer edge of a substrate arranged on the substrate support assembly during processing of the substrate in the substrate processing system.

In another feature, the annular channel includes N partitioning blocks that partition the annular channel into the N distinct sections.

In other features, the N injection ports are equidistant from each other, and each of the N partitioning blocks is arranged between two of the N injection ports and is equidistant from the two of the N injection ports.

In another feature, an outer portion of an upper surface of the annular body is proximate to an evacuation port of the substrate processing system.

In another feature, the edge ring is made of at least one of silicon and silicon carbide.

In still other features, a system comprises an edge ring having N injection ports, where N is an integer greater than 1, and configured to selectively deliver one or more gases. The system comprises a gas delivery system configured to supply the one or more gases to the N injection ports.

In other features, the edge ring comprises an annular channel disposed circumferentially along an inner diameter of the edge ring. The annular channel includes N distinct sections. The N injection ports are arranged circumferentially on the edge ring to respectively inject the one or more gases into the N distinct sections of the annular channel. The edge ring comprises a flange extending radially inwards from the inner diameter of the edge ring. A plurality of slits is arranged in the flange. The slits are in fluid communication with the annular channel and extend radially inwards from the annular channel to deliver the one or more gases.

In another feature, the plurality of slits is configured to deliver the one or more gases to an upper periphery of a substrate support assembly and under an outer edge of a substrate arranged on the substrate support assembly during processing of the substrate.

In other features, the annular channel includes N partitioning blocks that partition the annular channel into the N distinct sections. The N injection ports are equidistant from each other. Each of the N partitioning blocks is arranged between two of the N injection ports and is equidistant from the two of the N injection ports.

In another feature, the gas delivery system supplies the same gas from the one or more gases to the N injection ports.

In another feature, the gas delivery system supplies the same gas from the one or more gases to the N injection ports at the same flow rate.

In another feature, the gas delivery system supplies the same gas from the one or more gases to the N injection ports at different flow rates.

In another feature, the gas delivery system supplies M gases from the one or more gases to the N injection ports, where M is an integer, and 1<M≤N.

In another feature, the gas delivery system supplies M gases from the one or more gases to the N injection ports at the same flow rate, where M is an integer, and 1<M≤N.

In another feature, the gas delivery system supplies M gases from the one or more gases to the N injection ports at different flow rates, where M is an integer, and 1<M≤N.

In another feature, the one or more gases include one or more of a reactive gas and an inert gas.

In another feature, the system further comprises a substrate support assembly configured to support a substrate including a semiconductor wafer having an underside. The one or more gases are delivered to an area that is proximate to the underside of the semiconductor wafer.

In another feature, the one or more gases remove etch byproduct accumulated on the underside of the semiconductor wafer during processing.

In another feature, the system further comprises a substrate support assembly configured to support a substrate including a semiconductor wafer. The one or more gases are delivered in proximity to a periphery of the semiconductor wafer thereby reducing radial diffusion and improving edge radial uniformity.

In another feature, the system further comprises a processing chamber having one or more components. The one or more gases pre-coat at least one of the one or more components.

In another feature, the system further comprises a substrate support assembly configured to support a substrate including a semiconductor wafer. The one or more gases provide a dilution zone to dilute radicals diffused under a periphery of the semiconductor wafer and between the edge ring and the substrate support assembly.

In another feature, the system further comprises a substrate support assembly configured to support a substrate including a semiconductor wafer having an underside. The one or more gases are used to form a ring on the underside of the semiconductor wafer. The ring is used to determine whether the semiconductor wafer is centered on the substrate support assembly.

In another feature, the system further comprises a substrate support assembly configured to support a substrate including a semiconductor wafer. The one or more gases clean an area of the substrate support assembly below a periphery of the semiconductor wafer.

In other features, the gas delivery system includes a plurality of gas sources to supply the one or more gases, and a plurality of valves associated with the plurality of gas sources and the N injection ports. The system further comprises a controller configured to control the plurality of valves to selectively supply the one or more gases to the N injection ports at one or more flow rates.

In still other features, a method comprises arranging an edge ring around a substrate support assembly of a processing chamber. The edge ring includes an annular channel partitioned into N distinct sections, where N is an integer greater than 1. The method comprises supplying one or more gases to the N distinct sections of the annular channel respectively through N injection ports arranged circumferentially on the edge ring. The method comprises delivering the one or more gases via slits in a flange extending radially inwards from an inner diameter of the edge ring to an upper periphery of the substrate support assembly and under an outer edge of a substrate arranged on the substrate support assembly during processing of the substrate in the processing chamber.

In other features, the method further comprises delivering the one or more gases at the same flow rates, and tuning process uniformity at the outer edge of the substrate.

In other features, the method further comprises delivering the one or more gases at different flow rates, and compensating azimuthal process non-uniformities at the outer edge of the substrate.

In other features, the substrate includes a semiconductor wafer, the processing includes an etching process, and the one or more gases include a reactive gas, and the method further comprises preventing accumulation of material under the outer edge of the substrate by delivering the reactive gas from the edge ring during the etching process.

In other features, the substrate includes a semiconductor wafer, the processing includes an etching process, and the one or more gases include an inert gas, and the method further comprising protecting areas of the substrate support assembly during the etching process by delivering the inert gas from the edge ring during the etching process.

In other features, the substrate includes a cleaning wafer, the processing includes a cleaning process, and the one or more gases include an inert gas, and the method further comprising protecting components of the processing chamber proximate to the edge ring from wear during the cleaning process by delivering the inert gas from the edge ring during the cleaning process.

In other features, the substrate includes a cleaning wafer, the processing includes a cleaning process, and the one or more gases include a cleaning gas, and the method further comprising cleaning of components of the processing chamber proximate to the edge ring during the cleaning process by delivering the cleaning gas from the edge ring during the cleaning process.

In other features, the method further comprises depositing a material in a pattern under the outer edge of the substrate by using the one or more gases, and determining whether the substrate is centered on the substrate support assembly based on whether the pattern is concentric with a center of the substrate.

In another feature, the method further comprises depositing material on the outer edge of the substrate by delivering the one or more gases from the edge ring.

In another feature, the method further comprises depositing a coating on a component of the processing chamber proximate to the edge ring by delivering the one or more gases from the edge ring.

In another feature, the method further comprises supplying the one or more gases to the N distinct sections of the annular channel through the N injection ports at the same flow rate.

In another feature, the method further comprises supplying the one or more gases to the N distinct sections of the annular channel through the N injection ports at different flow rates.

In other features, the method further comprises supplying a first gas from the one or more gases through a first one of the N injection ports at a first flow rate, and supplying a second gas from the one or more gases through a second one of the N injection ports at a second flow rate.

In other features, the first gas includes a reactive gas, and the second gas includes an inert gas.

In other features, the first gas includes a first reactive gas, and the second gas includes a second reactive gas.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 shows an example of a substrate processing system including a processing chamber;

FIG. 2A shows a perspective view of an edge ring according to the present disclosure;

FIG. 2B shows a plan view of the edge ring according to the present disclosure;

FIGS. 2C-2G show various features of the edge ring according to the present disclosure;

FIG. 3A shows the edge ring used with a substrate support assembly according to the present disclosure;

FIG. 3B shows an example of a gas delivery system used with the edge ring according to the present disclosure;

FIGS. 3C-3E show examples of using the edge ring in a substrate processing system according to the present disclosure; and

FIG. 4 shows a comparison between process results when a tuning gas is supplied from the edge ring according to the present disclosure versus when the tuning gas is supplied from the top of a processing chamber.

In the drawings, reference numbers may be reused to identify similar and/or identical elements.

### DETAILED DESCRIPTION

Process gases and precursors are typically delivered to a wafer surface from an upper part of a processing chamber. For example, in dielectric etch tools, process gases are delivered from a showerhead that is designed to feed the process gases through an upper electrode of the processing chamber. In these tools, reactant or process gas delivery to the wafer surface depends on factors including a gap between the showerhead and the wafer surface, gas flow rate and pressure, confinement mechanism, and so on. Due to gas diffusion along the gap, the gas delivered at the edge of the wafer has a measurable effect on process results at the center of the wafer.

Presently, edge tuning gas is provided from the upper end of the processing chamber through the showerhead. The diffusion length scale of this feature results in process impact across the entire wafer, which is also dependent on the wafer gap. Furthermore, the tuning gas injected from the upper electrode impacts both the upper and lower electrodes of the processing chamber. Instead, a more local gas tuning knob can be provided that has a localized effect on the wafer with minimum impact to the upper electrode surface.

The present disclosure provides an edge ring that can deliver a tuning gas locally to a wafer edge by providing a gas feed path directly to the wafer bevel. The edge ring can deliver the tuning gas to the underside of the wafer bevel, close to a pump out (evacuation) path for gases in the process area of a reactor. This localized delivery of the tuning gas effectively reduces the diffusion length scale, which makes the effect of the tuning gas on the process more localized. Specifically, the edge ring locally injects the tuning gas at the extreme edge/bevel of the wafer from the underside, rather than the top, of the reactor. The edge ring thus provides a local gas tuning knob at the edge of the wafer during processing, with decreased sensitivity to the wafer gap.

As explained below in detail, the tuning gas can be used during wafer processing to prevent polymer byproduct accumulation on the underside of the wafer bevel. When implemented as a radially symmetric feature, the tuning gas can be used to tune extreme edge radial uniformity on a different length scale compared to tuning gas injected from the showerhead. In some implementations, the radial gas flow can also be non-uniformly distributed to compensate for edge dominated azimuthal non-uniformity during the process. Additionally, the tuning gas feature can be utilized during wafer-less auto-clean (WAC) and covered wafer auto clean (CWAC) sequences for improving cleaning efficiency on the edge of the ESC and on the edge ring. Further, the injected gas or gas mixture can be used for local deposition of chemistry onto the wafer bevel or edge ring. An inert gas can also be used to provide a buffer/dilution zone for areas of the ESC that are susceptible to radical attack during processing and/or to protect components that experience high wear rates during cleaning. In addition, the tuning gas can be injected to etch the underside of the wafer bevel to create a pattern that can be useful for wafer placement/centering as explained below.

By providing the tuning gas according to the present disclosure, the process tuning capability is more localized to the edge of the wafer due to the reduction in diffusion length. The tuning gas provides a highly localized source of radicals that can be used for cleaning the wafer bevel with limited impact to the wafer surface during cleaning and wafer processing. The effective radius of the tuning gas delivery can be adjusted by modulating gas flow to the wafer edge. Further, the tuning gas feature can also be utilized to selectively clean or deposit (pre-coat) material on edge rings or quartz coupling rings without significant impact to the film on the upper electrode.

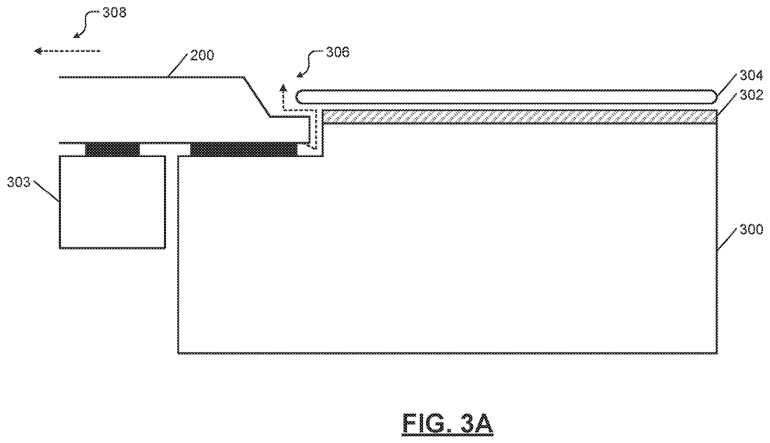

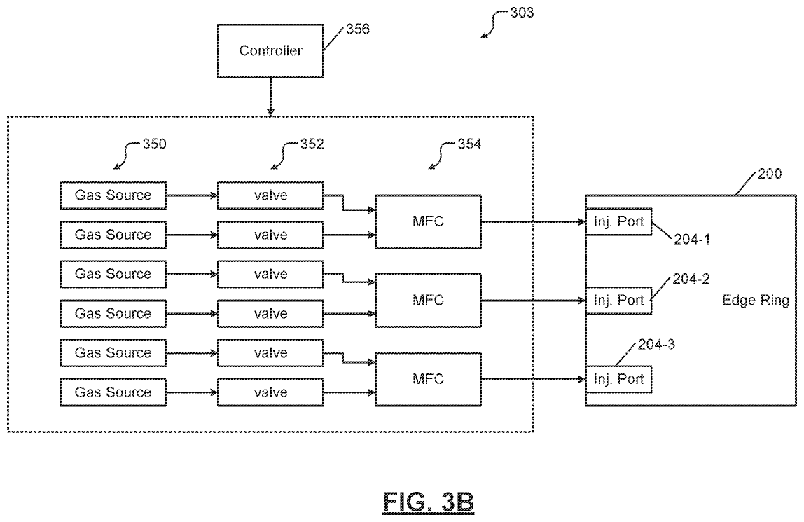

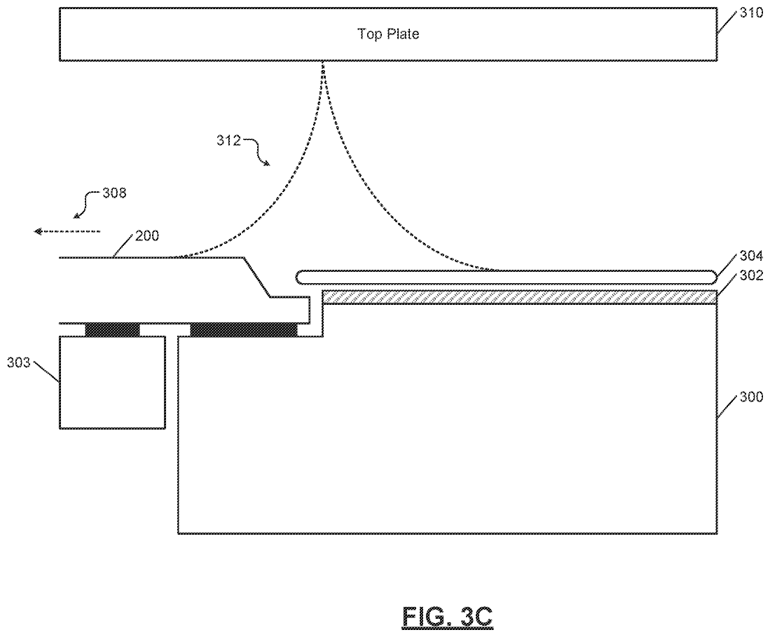

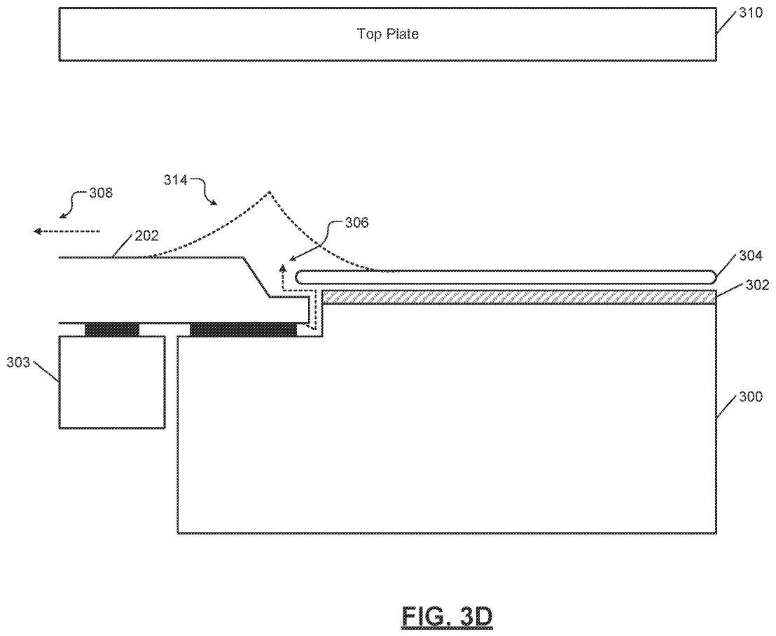

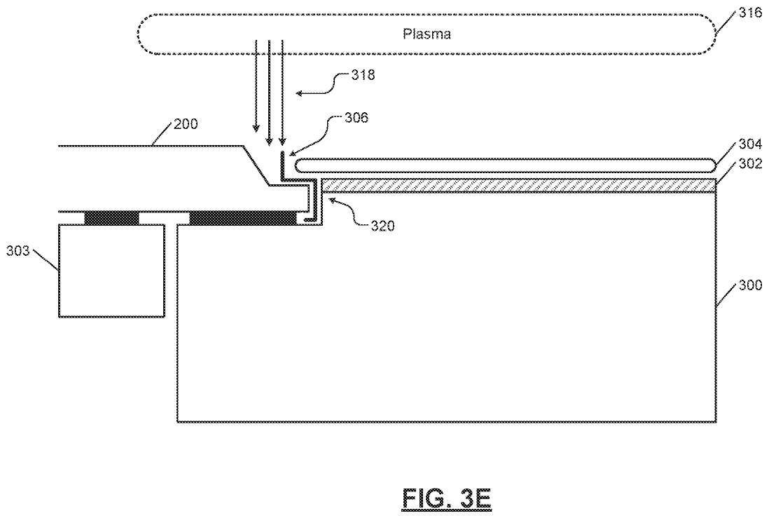

The various types of gas injections mentioned above, which are described below in detail with reference to FIGS. 3A-3E, are possible because the edge ring according to the present disclosure is partitioned into multiple sections and includes respective injection ports. By using the injection ports, one or more gases can be injected at various flow rates into the distinct sections of the edge ring. These and other features of the present disclosure are described below in detail.

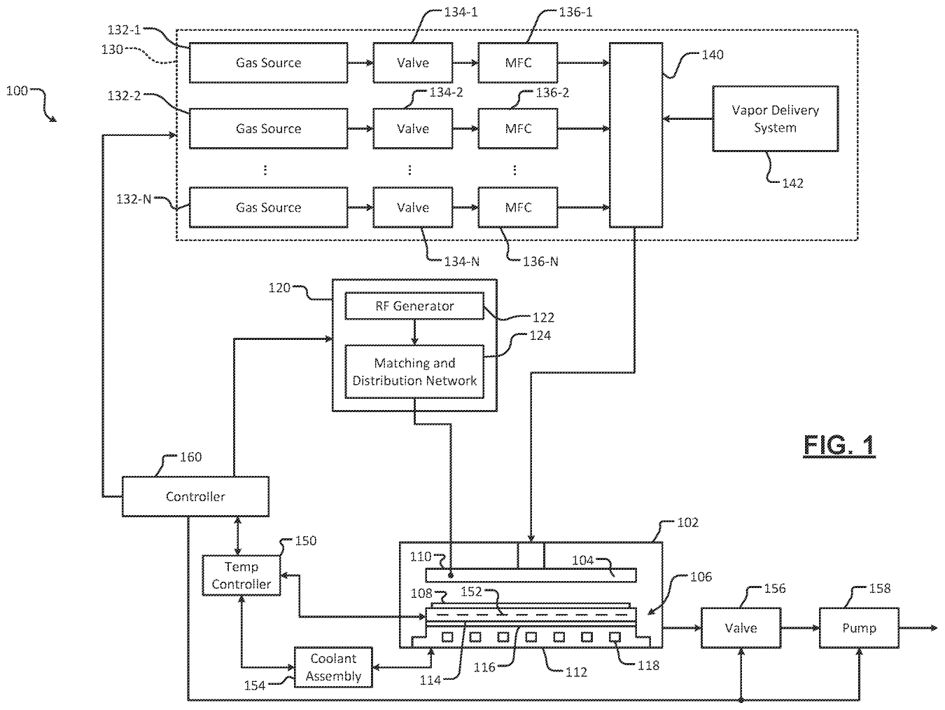

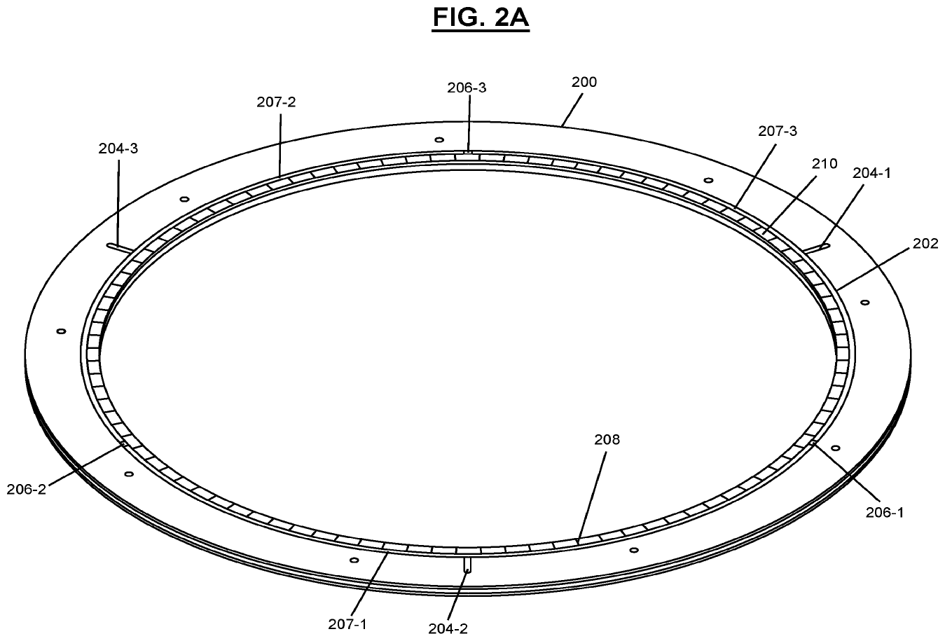

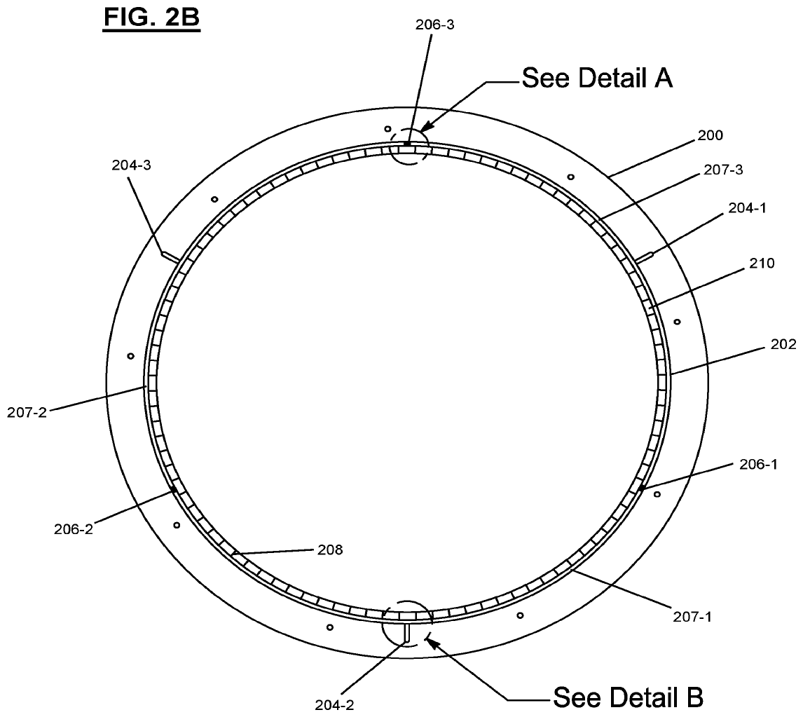

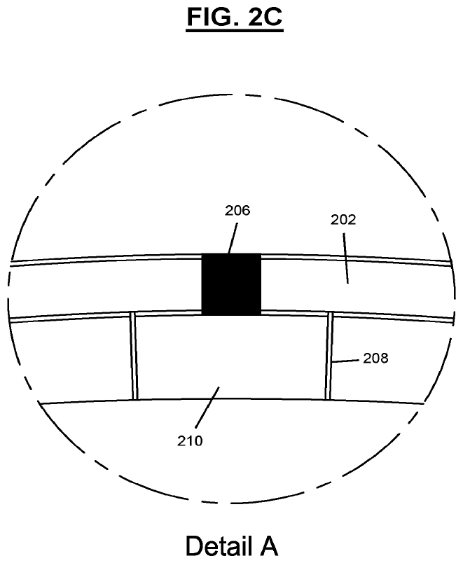

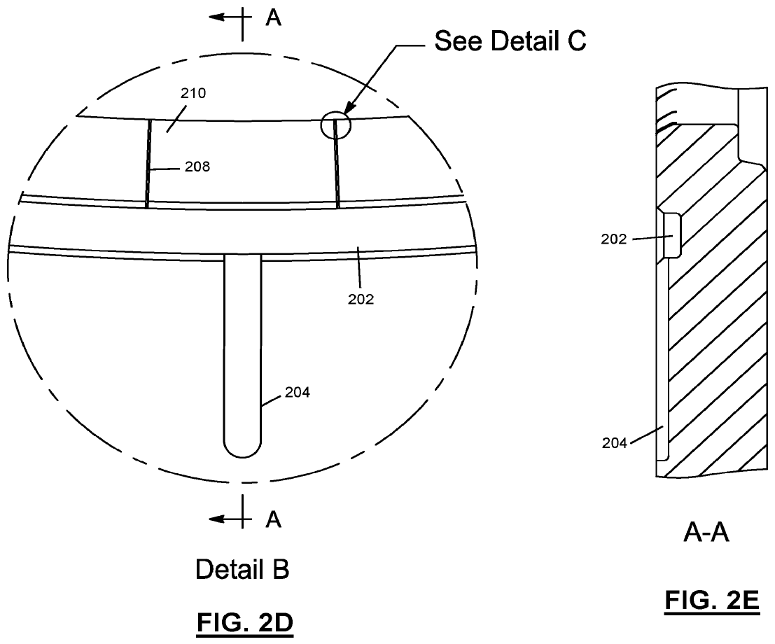

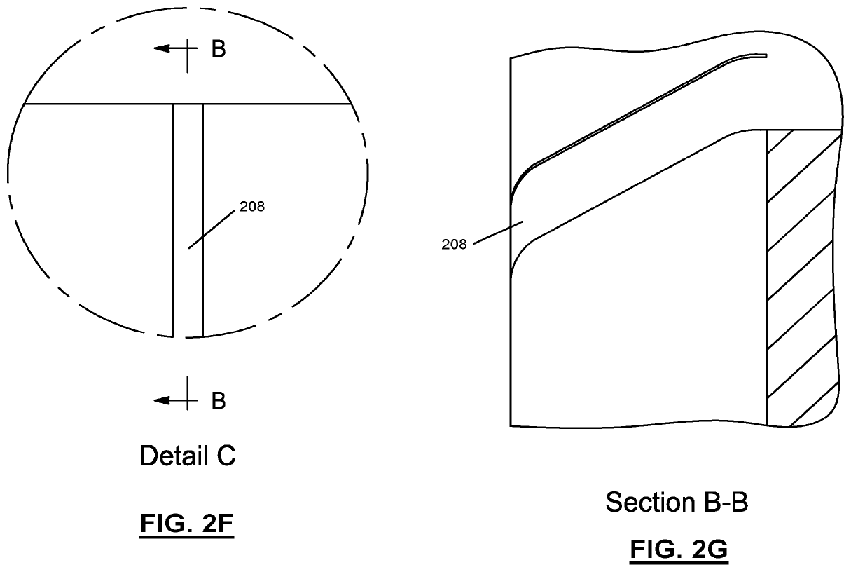

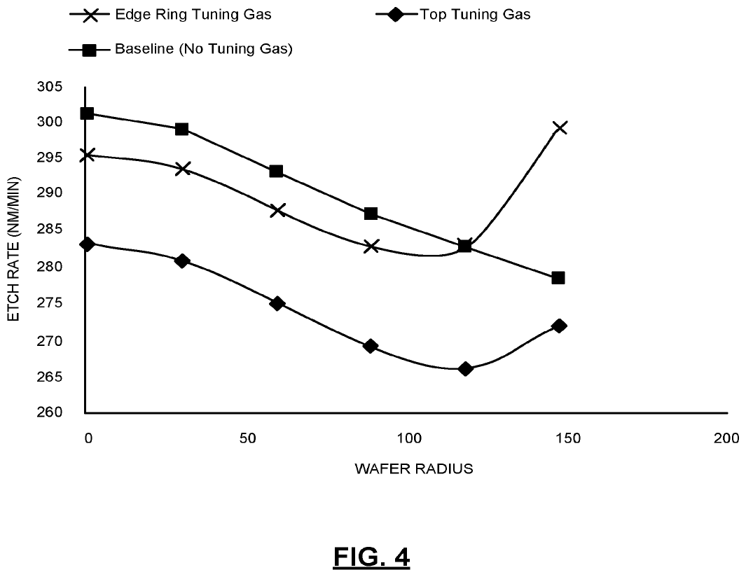

The present disclosure is organized as follows. FIG. 1 shows an example of a substrate processing system including a processing chamber in which the edge ring of the present disclosure can be used. FIGS. 2A-2G show various views and features of the edge ring according to the present disclosure. FIGS. 3A-3E show the edge ring in use according to the present disclosure. FIG. 4 shows that the tuning gas supplied from the edge ring according to the present disclosure produces better results than when the tuning gas is supplied from the top end of the processing chamber.

FIG. 1 shows an example of a substrate processing system 100 comprising a processing chamber 102 configured to generate capacitively coupled plasma. The processing chamber 102 that encloses other components of the substrate processing system 100 and contains RF plasma (if used). The processing chamber 102 comprises an upper electrode 104 and an electrostatic chuck (ESC) 106 or other type of substrate support. During operation, a substrate 108 is arranged on the ESC 106.

For example, the upper electrode 104 may include a gas distribution device 110 such as a showerhead that introduces and distributes process gases. The gas distribution device 110 may include a stem portion including one end connected to a top surface of the processing chamber 102. A base portion of the showerhead is generally cylindrical and extends radially outwardly from an opposite end of the stem portion at a location that is spaced from the top surface of the processing chamber 102. A substrate-facing surface or faceplate of the base portion of the showerhead includes a plurality of holes through which vaporized precursor, process gas, cleaning gas or purge gas flows. Alternately, the upper electrode 104 may include a conducting plate, and the gases may be introduced in another manner.

The ESC 106 comprises a baseplate 112 that acts as a lower electrode. The baseplate 112 supports a heating plate 114, which may correspond to a ceramic multi-zone heating plate. A thermal resistance layer 116 may be arranged between the heating plate 114 and the baseplate 112. The baseplate 112 may include one or more channels 118 for flowing coolant through the baseplate 112.

If plasma is used, an RF generating system (or an RF source) 120 generates and outputs an RF voltage to one of the upper electrode 104 and the lower electrode (e.g., the baseplate 112 of the ESC 106). The other one of the upper electrode 104 and the baseplate 112 may be DC grounded, AC grounded, or floating. For example, the RF generating system 120 may include an RF generator 122 that generates RF power that is fed by a matching and distribution network 124 to the upper electrode 104 or the baseplate 112. In other examples, while not shown, the plasma may be generated inductively or remotely and then supplied to the processing chamber 102.

A gas delivery system 130 includes one or more gas sources 132-1, 132-2, . . . , and 132-N (collectively gas sources 132), where N is an integer greater than zero. The gas sources 132 are connected by valves 134-1, 134-2, . . . , and 134-N (collectively valves 134) and mass flow controllers 136-1, 136-2, . . . , and 136-N (collectively mass flow controllers 136) to a manifold 140. A vapor delivery system 142 supplies vaporized precursor to the manifold 140 or another manifold (not shown) that is connected to the processing chamber 102. An output of the manifold 140 is fed to the processing chamber 102. The gas sources 132 may supply process gases, cleaning gases, and/or purge gases.

A temperature controller 150 may be connected to a plurality of thermal control elements (TCEs) 152 arranged in the heating plate 114. The temperature controller 150 may be used to control the plurality of TCEs 152 to control a temperature of the ESC 106 and the substrate 108. The temperature controller 150 may communicate with a coolant assembly 154 to control coolant flow through the channels 118. For example, the coolant assembly 154 may include a coolant pump, a reservoir, and one or more temperature sensors (not shown). The temperature controller 150 operates the coolant assembly 154 to selectively flow the coolant through the channels 118 to cool the ESC 106. A valve 156 and pump 158 may be used to evacuate reactants from the processing chamber 102. A system controller 160 controls the components of the substrate processing system 100.

FIGS. 2A-2G show various views and features of an edge ring 200 according to the present disclosure. FIG. 2A shows a perspective view of the edge ring 200. FIG. 2B shows a plan view of the edge ring 200. FIGS. 2C-2G show the features of the edge ring 200 in detail.

In FIGS. 2A and 2B, the edge ring 200 includes an annular channel 202. The annular channel 202 is not fully cut all the way around the circumference of the edge ring 200. Instead, the annular channel 202 is partitioned into distinct sections that are not in fluid communication with each other as explained below. A cross-section of the annular channel 202 is shown in FIG. 2E.

The edge ring 200 includes a plurality of injection ports 204-1, 204-2, and 204-3 (collectively injection ports 204) arranged along the periphery or perimeter (circumference) of the edge ring 200. One or more gases can be injected into the annular channel 202 through the injection ports 204 as described below in detail. FIG. 2D shows an additional view of one of the injection ports 204.

While three injection ports are shown for example only, the edge ring 200 can include any number of injection ports. For example, when the edge ring 200 includes two injection ports, the injection ports may be arranged at diametrically opposite locations along the circumference of the edge ring 200. For example, when the edge ring 200 includes two or more injection ports, the injection ports may be distributed symmetrically around the edge ring 200. For example, when the edge ring 200 includes three injection ports, the injection ports form vertices of an equilateral triangle that lie along the circumference of the edge ring 200. Alternatively, the three injection ports may form vertices of an isosceles triangle that lie along the circumference of the edge ring 200. For example, when the edge ring 200 includes four injection ports, the injection ports form vertices of a square that lie along the circumference of the edge ring 200. Alternatively, the four injection ports may form vertices of a rectangle or a rhombus that lie along the circumference of the edge ring 200, and so on. Many other geometric arrangements of the injection ports 204 along the circumference of the edge ring 200 are contemplated.

The annular channel 202 is partitioned into a plurality of disjoint sections (also called portions or partitions) by partitioning blocks (see element 206 in FIG. 2C) arranged (e.g., embedded) in the annular channel 202. The number of partitioning blocks in the annular channel 202 and the number of sections of the annular channel 202 are equal to the number of injection ports 204. For example, in FIGS. 2A and 2B, since three injection ports 204 are shown, the annular channel 202 is partitioned into three sections 207-1, 207-2, and 207-3 (collectively sections 207) by three partitioning blocks 206-1, 206-2, and 206-3 (collectively partitioning blocks 206).

The partitioning blocks 206 are arranged in a similar geometric arrangement as the injection ports 204. The partitioning blocks 206 are equidistant from the injection ports 204 and from each other. For example, in the example shown in FIGS. 2A and 2B, since the three injection ports 204 are spaced 120 degrees apart, the three partitioning blocks 206 are also spaced 120 degrees apart and are spaced 60 degrees apart from the three injection ports 204. Each partitioning block 206 is equidistant from its neighboring injection ports 204 on either side of the partitioning block 206. In the example shown in FIGS. 2A and 2B, the three partitioning blocks 206 also lie on vertices of an equilateral triangle similar to the three injection ports 204 that lie on vertices of an equilateral triangle.

The edge ring 200 includes a flange 210 that extends radially inward (i.e., towards the center of the edge ring 200) from an inner diameter of the edge ring 200. The flange 210 includes numerous slits 208 that are in fluid communication with the annular channel 202 and that extend radially inward from the annular channel 202. The gas or gases injected into the injection ports 204 enter the respective sections 207 of the annular channel 202 and exit from the slits 208 associated with the respective sections 207 of the annular channel 202. FIGS. 2C and 2D show additional views of one of the slits 208. FIGS. 2F and 2G show one of the slits 208 in detail.

For example, the edge ring 200 can be made of silicon and silicon carbide. While silicon is challenging machine, the edge ring 200 can be made of silicon, which is preferred if other components of the processing chamber are also made of silicon. In general, the edge ring can be made of any machinable ceramic or non-ceramic material used for manufacturing components of a processing chamber. The material can be selected based on the process being performed in the processing chamber and the type of substrate processing tool used.

FIGS. 3A-3E show the edge ring 200 in use according to the present disclosure. FIG. 3A shows gas delivery using the edge ring 200. FIG. 3B shows a gas delivery system that supplies one or more gases to the edge ring 200. FIGS. 3C and 3D show extreme edge uniformity control using the edge ring 200. FIG. 3E shows an inert gas barrier created using the edge ring 200 to slow radical attack on the ESC.

FIG. 3A shows an example of a substrate support assembly 300 (e.g., the ESC 106 shown in FIG. 1) comprising a baseplate 302 (e.g., the baseplate 112 shown in FIG. 1) to support a wafer 304 (e.g., the substrate 108 shown in FIG. 1). While not shown for simplicity of illustration, the baseplate 302 includes a ceramic/top layer which supports the wafer 304. A gas delivery system 303 (e.g., the gas delivery system 130 shown in FIG. 1) delivers one or more gases to the edge ring 200. Examples of connections between the gas delivery system 303 and the edge ring 200 are shown in FIG. 3B.

The edge ring 200 delivers the tuning gas as shown at 306. The point of gas delivery from the edge ring 200 to the underside of the wafer 304 is closer to the pump out or evacuation path of the processing chamber shown at 308, which helps in keeping the gas delivery from the edge ring 200 to the wafer edge highly localized (i.e., restricted to the wafer edge) as shown at 306.

FIG. 3B shows the gas delivery system 303. The gas delivery system 303 comprises a plurality of gas sources 350, a plurality of valves 352, a plurality of mass flow controllers 354, and a controller 356 (e.g., the controller 160 shown in FIG. 1). The gas sources 350, valves 352, and mass flow controllers 354 can be similar to the gas sources 132, valves 134, and mass flow controllers 136 shown in FIG. 1. The gas sources 350 can supply one or more tuning gases, an inert gas, and other gases described below. The controller 356 controls the valves 352 and the mass flow controllers 354 to supply the same gas, different gases, or gas mixtures, which can be supplied at the same or different flow rates and pressures, to the injection ports 204 of the edge ring 200 as described below.

Sometimes while wafer processing is being performed in a processing chamber (e.g., the processing chamber 102 shown in FIG. 1), since the backside of the wafer 304 is not exposed to the direct ion bombardment of the plasma (not shown), polymer or some other type of etch byproduct residue tends to accumulate on the backside of the wafer 304. For example, reactants and radicals accumulating on the underside of the wafer bevel do not get etched away and cause a ring shaped deposit on the underside of the wafer bevel. This problem can be solved in many ways.

For example, the gas injected from the edge ring 200 can be selected such that the injected gas can chemically react with the material accumulating on the underside of the wafer bevel. For example, the gas can include a reactive gas. Alternatively, the gas injected from the edge ring 200 can include an inert gas that can dilute or reduce the concentration of the material and prevent the material from accumulating on the underside of the wafer bevel. The injected inert gas also does not interfere with the ongoing process being performed in the processing chamber. Thus, the locally injected gas or gases from the edge ring 200 can control the chemistry or chemical reaction in the vicinity of the underside of the wafer bevel to prevent the deposition of etch byproducts on the underside of the wafer bevel during and without affecting the processing ongoing in the processing chamber.

FIGS. 3C and 3D show a top plate 310 arranged above the substrate support assembly 300 in a processing chamber (e.g., the processing chamber 102 shown in FIG. 1). A showerhead (e.g., the showerhead 104 shown in FIG. 1 is disposed in the top plate 310. The distance between the showerhead in the top plate 310 and the wafer 304 is typically such that the gas being delivered from the showerhead to the wafer 304 diffuses radially between the showerhead to the wafer 304 as shown at 312 in FIG. 3B.

Notably, the distance between the point of gas injection from the edge ring 200 and the wafer edge is significantly smaller than the distance between the showerhead in the top plate 310 and the wafer 304. Reducing the distance between the point of gas injection from the edge ring 200 and the wafer edge reduces the extent of the radial diffusion near the wafer edge as shown at 314 in FIG. 3D. Thus, the diffusion can be controlled and consequently the extreme edge radial uniformity can be improved by injecting the tuning gas from the edge ring 200 closer to the wafer edge. That is, the non-uniformity due to diffusion near the wafer edge can be reduced by making the gas injection point from the edge ring 200 close to the wafer edge.

By controlling the valves 352 and mass flow controllers 354 using the controller 356, the gas flow can be distributed from the edge ring 200 radially uniformly or non-uniformly. For example, an etch gas can be injected uniformly (i.e., radially symmetrically) through the injection ports 204 so that the same concentration of the etch gas is injected azimuthally all around the edge ring 200. The etch gas can also be injected non-uniformly (i.e., radially asymmetrically) through the injection ports 204 so that different amounts of the etch gas can be delivered in different areas around the edge ring 200. For example, the flow rate of the etch gas through each of the injection ports 204 can be individually controlled.

Further, different gases can be selectively injected through the injection ports 204. Different gases can be injected through the injection ports 204 at different flow rates in a controlled manner to address various non-uniformity issues including azimuthal non-uniformities. For example, the same (i.e., a single) gas can be injected at the same or different flow rates through the injection ports 204. Alternatively, two or more different gases can be injected through respective injection ports 204 at the same flow rate or at respective different flow rates; etc. For example, the different gases can include a combination of different reactive gases, a combination of an inert gas and reactive gases, and so on.

The gas injection through the edge ring 200 has other applications well. For example, during CWAC, areas of the substrate support assembly 300 below the wafer overhang are difficult to clean. These areas can be cleaned using the gas or gases injected through the edge ring 200. Further, in some processing chambers, some of the components of the processing chamber may be pre-coated. The pre-coating can be performed by injecting gases through the edge ring 200.

FIG. 3E shows that an inert gas can be injected through the edge ring 200 to provide a buffer or a dilution zone to dilute radicals that can diffuse under the wafer 304 and between the edge ring 200 and the substrate support assembly 300 as shown at 318. These radicals can attack the bond between the substrate support assembly 300 and the baseplate 302 shown at 320, for example. The dilution of these radicals by the inert gas injected through the edge ring 200 can delay, minimize, or prevent the attack. This type of purging of the radicals from the crevices can be performed while a wafer is being processed, while the processing chamber is cleaned (where this step can be a separate purge step), or when the processing chamber is idle (where this can be a standalone purge step).

Further, some components of the processing chamber in the vicinity of the edge ring 200 can be protected (e.g., pre-coated) and/or cleaned selectively using the edge ring gas injection scheme. For example, some components may experience high wear during chamber cleaning process. The dilution method described above can be used to prevent excessive wear of such components during the cleaning process. Further, a preferential protection scheme can be employed in which an inert gas is injected at locations where a component needs to be protected during a cleaning process. Conversely, a reactive gas is injected to enhance cleaning at locations where the cleaning process cannot sufficiently clean a component.

The various types of gas injections described above with reference to FIGS. 3A-3E are possible because the edge ring is partitioned into multiple sections 207 and includes respective injection ports 204. Further, the various types of gas injections are possible because the gas delivery system 303 can supply different gases in different ways described above using the valves 352 and mass flow controllers 354.

When the wafer 304 is arranged on the substrate support assembly 300 during processing, the wafer 304 needs to be centered on the substrate support assembly 300. The edge ring gas injection system described above can be used to deposit material on the area of the underside of the wafer 304 that overhangs from the substrate support assembly 300. This deposition creates a ring on the underside of the wafer 304. The ring can be examined to verify whether the wafer 304 is centered on the substrate support assembly 300. The wafer 304 is centered on the substrate support assembly 300 if the ring is concentric with the center of the wafer 304.

FIG. 4 shows a comparison between process results when a tuning gas is supplied from the edge ring 200 versus when the tuning gas is supplied from the top end of the processing chamber. The graph shows that the tuning gas supplied from the edge ring 200 produces better results than when the tuning gas is supplied from the top end of the processing chamber.

The foregoing description is merely illustrative in nature and is not intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims.

It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another are within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In some implementations, a controller is part of a system, which may be part of the above-described examples. Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems.

The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software).

Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process.

In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control.

Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

What is claimed is:

1. An edge ring for a substrate processing system, the edge ring comprising:
an annular body;
an annular channel disposed in the annular body circumferentially along an inner diameter of the annular body, the annular channel including N distinct sections, where N is an integer greater than 1;
N injection ports arranged circumferentially on the annular body to respectively inject one or more gases into the N distinct sections of the annular channel;
a flange extending radially inwards from the inner diameter of the annular body; and
a plurality of slits arranged in the flange, the slits being in fluid communication with the annular channel and extending radially inwards from the annular channel to deliver the one or more gases.

2. The edge ring of claim 1 wherein the plurality of slits is configured to deliver the one or more gases to an upper periphery of a substrate support assembly and under an outer edge of a substrate arranged on the substrate support assembly during processing of the substrate in the substrate processing system.

3. The edge ring of claim 1 wherein the annular channel includes N partitioning blocks that partition the annular channel into the N distinct sections.

4. The edge ring of claim 3 wherein:
the N injection ports are equidistant from each other; and
each of the N partitioning blocks is arranged between two of the N injection ports and is equidistant from the two of the N injection ports.

5. The edge ring of claim 1 wherein an outer portion of an upper surface of the annular body is proximate to an evacuation port of the substrate processing system.

6. The edge ring of claim 1 wherein the edge ring is made of at least one of silicon and silicon carbide.

7. A system comprising:
an edge ring having N injection ports, where N is an integer greater than 1, and configured to selectively deliver one or more gases; and
a gas delivery system configured to supply the one or more gases to the N injection ports.

8. The system of claim 7 wherein the edge ring comprises:
an annular channel disposed circumferentially along an inner diameter of the edge ring, the annular channel including N distinct sections;
wherein the N injection ports are arranged circumferentially on the edge ring to respectively inject the one or more gases into the N distinct sections of the annular channel;
a flange extending radially inwards from the inner diameter of the edge ring; and
a plurality of slits arranged in the flange, the slits being in fluid communication with the annular channel and extending radially inwards from the annular channel to deliver the one or more gases.

9. The system of claim 8 wherein the plurality of slits is configured to deliver the one or more gases to an upper periphery of a substrate support assembly and under an outer edge of a substrate arranged on the substrate support assembly during processing of the substrate.

10. The system of claim 8 wherein:
the annular channel includes N partitioning blocks that partition the annular channel into the N distinct sections;
the N injection ports are equidistant from each other; and
each of the N partitioning blocks is arranged between two of the N injection ports and is equidistant from the two of the N injection ports.

11. The system of claim 7 wherein the gas delivery system supplies the same gas from the one or more gases to the N injection ports.

12. The system of claim 7 wherein the gas delivery system supplies the same gas from the one or more gases to the N injection ports at the same flow rate.

13. The system of claim 7 wherein the gas delivery system supplies the same gas from the one or more gases to the N injection ports at different flow rates.

14. The system of claim 7 wherein the gas delivery system supplies M gases from the one or more gases to the N injection ports, where M is an integer, and 1<M≤N.

15. The system of claim 7 wherein the gas delivery system supplies M gases from the one or more gases to the N injection ports at the same flow rate, where M is an integer, and 1<M≤N.

16. The system of claim 7 wherein the gas delivery system supplies M gases from the one or more gases to the N injection ports at different flow rates, where M is an integer, and 1<M≤N.

17. The system of claim 7 wherein the one or more gases include one or more of a reactive gas and an inert gas.

18. The system of claim 7 further comprising:
a substrate support assembly configured to support a substrate including a semiconductor wafer having an underside;
wherein the one or more gases are delivered to an area that is proximate to the underside of the semiconductor wafer.

19. The system of claim 18 wherein the one or more gases remove etch byproduct accumulated on the underside of the semiconductor wafer during processing.

20. The system of claim 7 further comprising:
a substrate support assembly configured to support a substrate including a semiconductor wafer;
wherein the one or more gases are delivered in proximity to a periphery of the semiconductor wafer thereby reducing radial diffusion and improving edge radial uniformity.

21. The system of claim 7 further comprising a processing chamber having one or more components, wherein the one or more gases pre-coat at least one of the one or more components.

22. The system of claim 7 further comprising:
a substrate support assembly configured to support a substrate including a semiconductor wafer;
wherein the one or more gases provide a dilution zone to dilute radicals diffused under a periphery of the semiconductor wafer and between the edge ring and the substrate support assembly.

23. The system of claim 7 further comprising:
a substrate support assembly configured to support a substrate including a semiconductor wafer having an underside;
wherein the one or more gases are used to form a ring on the underside of the semiconductor wafer; and
wherein the ring is used to determine whether the semiconductor wafer is centered on the substrate support assembly.

24. The system of claim 7 further comprising:
a substrate support assembly configured to support a substrate including a semiconductor wafer;
wherein the one or more gases clean an area of the substrate support assembly below a periphery of the semiconductor wafer.

25. The system of claim 7 wherein:
the gas delivery system includes:
a plurality of gas sources to supply the one or more gases; and
a plurality of valves associated with the plurality of gas sources and the N injection ports; and
the system further comprises a controller configured to control the plurality of valves to selectively supply the one or more gases to the N injection ports at one or more flow rates.

26. A method comprising:
arranging an edge ring around a substrate support assembly of a processing chamber, the edge ring including an annular channel partitioned into N distinct sections, where N is an integer greater than 1;
supplying one or more gases to the N distinct sections of the annular channel respectively through N injection ports arranged circumferentially on the edge ring; and
delivering the one or more gases via slits in a flange extending radially inwards from an inner diameter of the edge ring to an upper periphery of the substrate support assembly and under an outer edge of a substrate arranged on the substrate support assembly during processing of the substrate in the processing chamber.

27. The method of claim 26 further comprising:
delivering the one or more gases at the same flow rates; and
tuning process uniformity at the outer edge of the substrate.

28. The method of claim 26 further comprising:
delivering the one or more gases at different flow rates; and
compensating azimuthal process non-uniformities at the outer edge of the substrate.

29. The method of claim 26 wherein the substrate includes a semiconductor wafer, the processing includes an etching process, and the one or more gases include a reactive gas, the method further comprising preventing accumulation of material under the outer edge of the substrate by delivering the reactive gas from the edge ring during the etching process.

30. The method of claim 26 wherein the substrate includes a semiconductor wafer, the processing includes an etching process, and the one or more gases include an inert gas, the method further comprising protecting areas of the substrate support assembly during the etching process by delivering the inert gas from the edge ring during the etching process.

31. The method of claim 26 wherein the substrate includes a cleaning wafer, the processing includes a cleaning process, and the one or more gases include an inert gas, the method further comprising protecting components of the processing chamber proximate to the edge ring from wear during the cleaning process by delivering the inert gas from the edge ring during the cleaning process.

32. The method of claim 26 wherein the substrate includes a cleaning wafer, the processing includes a cleaning process, and the one or more gases include a cleaning gas, the method further comprising cleaning of components of the processing chamber proximate to the edge ring during the cleaning process by delivering the cleaning gas from the edge ring during the cleaning process.

33. The method of claim 26 further comprising:
depositing a material in a pattern under the outer edge of the substrate by using the one or more gases; and
determining whether the substrate is centered on the substrate support assembly based on whether the pattern is concentric with a center of the substrate.

34. The method of claim 26 further comprising depositing material on the outer edge of the substrate by delivering the one or more gases from the edge ring.

35. The method of claim 26 further comprising depositing a coating on a component of the processing chamber proximate to the edge ring by delivering the one or more gases from the edge ring.

36. The method of claim 26 further comprising supplying the one or more gases to the N distinct sections of the annular channel through the N injection ports at the same flow rate.

37. The method of claim 26 further comprising supplying the one or more gases to the N distinct sections of the annular channel through the N injection ports at different flow rates.

38. The method of claim 26 further comprising:
supplying a first gas from the one or more gases through a first one of the N injection ports at a first flow rate; and
supplying a second gas from the one or more gases through a second one of the N injection ports at a second flow rate.

39. The method of claim 38 wherein the first gas includes a reactive gas and wherein the second gas includes an inert gas.

40. The method of claim 38 wherein the first gas includes a first reactive gas and wherein the second gas includes a second reactive gas.
